(19) United States
(12) Patent Application Publication
(10) Pub. No.: US 2013/0092085 A1
(43) Pub. Date: Apr. 18, 2013

(54) LINEAR ATOMIC LAYER DEPOSITION APPARATUS

(71) Applicant: Synos Technology, Inc., Fremont, CA (US)

(72) Inventor: Sang In LEE, Sunnyvale, CA (US)

(73) Assignee: SYNOS TECHNOLOGY, INC., Fremont, CA (US)

(21) Appl. No.: 13/647,974

(22) Filed: Oct. 9, 2012

Related U.S. Application Data
(60) Provisional application No. 61/548,102, filed on Oct. 17, 2011.
(60) Provisional application No. 61/558,124, filed on Nov. 10, 2011.
(60) Provisional application No. 61/593,747, filed on Feb. 1, 2012.

(51) Int. Cl. C23C 16/458; C23C 16/04

(52) U.S. Cl. 118/719; 118/712

(57) ABSTRACT

Embodiments relate to a linear deposition apparatus with mechanism for securing a shadow mask and a substrate onto a susceptor. The linear deposition apparatus includes a set of members attached to latches that are raised to unlock the shadow mask and the substrate from the susceptor. The latches are lowered to secure the shadow mask and the substrate to the susceptor. Another set of members are provided in the linear deposition apparatus to move and align the shadow mask with the substrate. The linear deposition apparatus also includes a main body and two wings provided at both sides of the main body to receive the substrate as the substrate moves linearly to expose the substrate to materials or radicals injected by reactors.

### CROSS-REFERENCE TO RELATED APPLICATION

This application claims priority under 35 U.S.C. §119(e) to co-pending U.S. Provisional Patent Application No. 61/548,102, filed on Oct. 17, 2011; U.S. Provisional Patent Application No. 61/558,124, filed on Nov. 10, 2011; and U.S. Provisional Patent Application No. 61/593,747, filed on Feb. 1, 2012, which are incorporated by reference herein in their entirety.

### BACKGROUND

1. Field of Art

The disclosure relates to apparatus for depositing materials on a substrate by moving the substrate in a linear manner relative to reactors placed above the substrate.

2. Description of the Related Art

An atomic layer deposition (ALD) is a thin film deposition technique for depositing one or more layers of material on a substrate. ALD uses two types of chemical, one is a source precursor and the other is a reactant precursor. Generally, ALD includes four stages: (i) injection of a source precursor, (ii) removal of a physical adsorption layer of the source precursor, (iii) injection of a reactant precursor, and (iv) removal of a physical adsorption layer of the reactant precursor.

ALD can be a slow process that can take an extended amount of time or many repetitions before a layer of desired thickness can be obtained. Hence, to expedite the process, a vapor deposition reactor with a unit module (so-called a linear injector), as described in U.S. Patent Application Publication No. 2009/0165715 or other similar devices may be used to expedite ALD process. The unit module includes an injection unit and an exhaust unit for a source material (a source module), and an injection unit and an exhaust unit for a reactant (a reactant module).

A conventional ALD vapor deposition chamber has one or more sets of reactors for depositing ALD layers on substrates. As the substrate passes below the reactors, the substrate is exposed to the source precursor, a purge gas and the reactant precursor. The source precursor molecules deposited on the substrate reacts with reactant precursor molecules or the source precursor molecules are replaced with the reactant precursor molecules to deposit a layer of material on the substrate. After exposing the substrate to the source precursor or the reactant precursor, the substrate may be exposed to the purge gas to remove excess source precursor molecules or reactant precursor molecules from the substrate.

### SUMMARY

Embodiments relate to an apparatus for depositing a layer of material on a substrate using atomic layer deposition where a length of the susceptor is longer than the substrate by at least twice the width of a plurality of the reactors to place at least a portion of the susceptor in paths of the injected source precursor and the injected reactant precursor at the first end position and the second end position. A plurality of reactors is configured to inject source precursor and reactant precursor for performing the atomic layer deposition on the substrate. The susceptor moves relative to the plurality of reactors between a first end position and a second end position in a direction that is substantially perpendicular to a direction in which source precursor and reactant precursor are injected onto the substrate by the plurality of reactors. The extended length of the susceptor place at least a portion of the susceptor in paths of the injected source precursor and the injected reactant precursor at the first end position and the second end position of the susceptor. The apparatus also includes at least one component for moving the susceptor between the first position and the second position.

In one embodiment, the plurality of reactors includes an injector placed at an edge facing the first end position and another injector placed at an opposite edge facing the second end position to inject purge gas to prevent the source precursor or the reactant precursor from leaking outside a region between the plurality of reactors and the susceptor and to desorb physisorbed source precursor molecules or the physisorbed reactant precursor molecules.

In one embodiment, the apparatus also includes a body, a first wing extending from one end of the body and a second wing extending from an opposite end of the body. The first wing receives a part of the susceptor when the susceptor is at the first end position, and the second wing receives another part of the susceptor when the susceptor is at the second end position.

In one embodiment, the body is formed with a door for moving the substrate into or out of interior of the body.

In one embodiment, purge gas is injected into interior of the first wing and the second wing towards the body to prevent the source precursor or the reactant precursor from entering the interior of the first wing and the second wing.

In one embodiment, the plurality of reactors include a radical reactor for generating radicals.

In one embodiment, the susceptor further comprises one or more latches for securing a shadow mask onto the substrate.

In one embodiment, the apparatus further includes a camera for aligning the shadow mask and the substrate. The latches may lock the shadow mask and the substrate into position after the shadow mask and the substrate are aligned.

In one embodiment, the apparatus further includes lifting rods placed below the substrate to lift the substrate from the susceptor for unloading the substrate from the susceptor.

In one embodiment, the susceptor is configured to fold to reduce a length of the susceptor when mounting or unloading the substrate.

In one embodiment, the susceptor includes a first part and a second part hinged to the first part. The first part is rotated relative to the second part when mounting or unloading the substrate.

In one embodiment, the susceptor includes a first part and a second part connected to the first part via a link. The second part is formed with a cavity to hold the first part when the susceptor is folded.

In one embodiment, a door for moving the substrate into or out of interior of the body is formed at a side of the body adjacent to a part of the susceptor being folded.

In one embodiment, the plurality of reactors comprise a first reactor for injecting the source precursor and a second reactor for injecting the reactant precursor.

In one embodiment, the substrate moves across the first reactor and the second reactor at a constant speed to deposit a material on the substrate.

In one embodiment, the apparatus includes a valve assembly connected to the first reactor to provide the source precursor to the first reactor while the substrate passes across the first reactor but provide purge gas to the first reactor before or after the substrate passes across the first reactor.

In one embodiment, the valve assembly is connected to the second reactor to provide the reactant precursor to the second reactor while the substrate passes across the second reactor provide but provide purge gas to the second reactor before or after the substrate passes across the second reactor.

In one embodiment, the apparatus further comprises a third reactor and a fourth reactor for injecting purge gas onto the substrate to remove physisorbed precursor or material from the substrate.

### BRIEF DESCRIPTION OF DRAWINGS

FIG. 1A is a perspective view of a linear deposition apparatus, according to one embodiment.

FIG. 1B is a cross sectional view of the linear deposition apparatus of FIG. 1A, according to one embodiment.

FIG. 1C is another cross sectional view of the linear deposition apparatus of FIG. 1A, according to one embodiment.

FIG. 2 is a plan view of a susceptor with a substrate and a shadow mask mounted thereon, according to one embodiment.

FIG. 3 is an enlarged sectional view of a susceptor illustrating a mechanism for mounting or unloading the substrate and the shadow mask, according to one embodiment.

FIG. 4 is a sectional view of reactors in the linear deposition apparatus, according to one embodiment.

FIG. 5A is a cross sectional view of a foldable susceptor, according to one embodiment.

FIG. 5B is a cross sectional view of a linear deposition apparatus illustrating a susceptor at a location for mounting or unloading a substrate, according to another embodiment.

FIG. 5C is a cross sectional view of the linear deposition apparatus illustrating the susceptor unfolded and moving towards an opposite end of the linear deposition apparatus, according to one embodiment.

FIG. 5D is a cross sectional view of the linear deposition apparatus illustrating the susceptor moved to the opposite end of the linear deposition apparatus, according to one embodiment.

FIGS. 6A through 6C are cross sectional views of a foldable susceptor, according to another embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to a linear deposition apparatus including a main body and one or more wings provided at one or both sides of the main body to receive portions of a substrate as the substrate moves linearly to expose the substrate to source precursor and reactant precursor injected by reactors. The linear deposition apparatus also include a mechanism for securing a shadow mask and a substrate onto a susceptor. The linear deposition apparatus includes a set of members attached to latches that are raised to unlock the shadow mask and the substrate from the susceptor. The latches are lowered to secure the shadow mask and the substrate to the susceptor. Another set of members are provided in the linear deposition apparatus to move and align the shadow mask with the substrate.

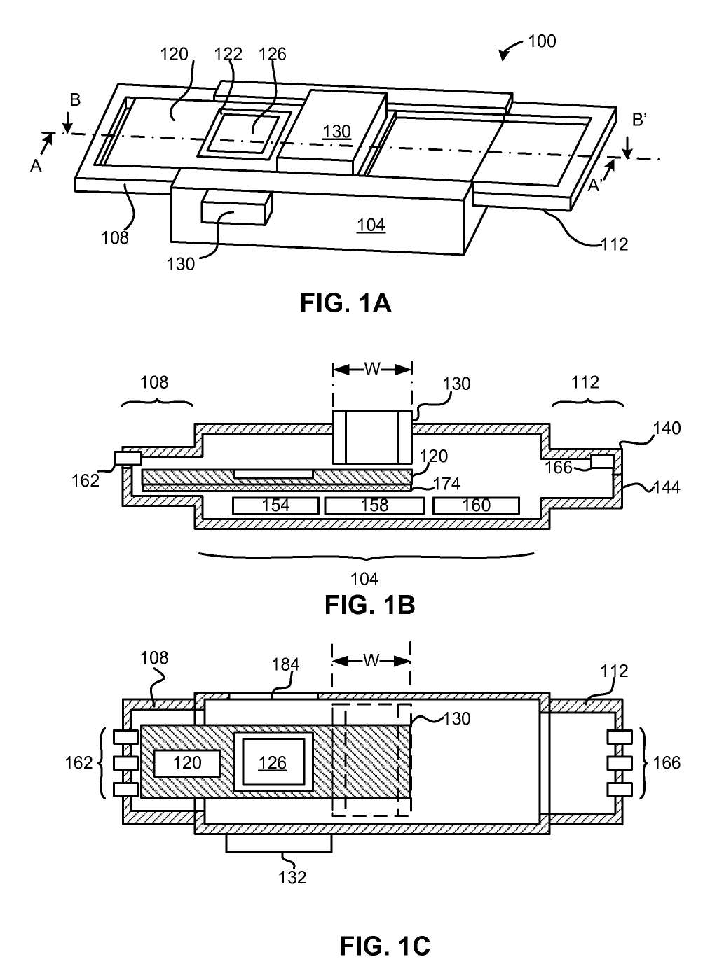

FIG. 1A is a perspective view of a linear deposition apparatus 100, according to one embodiment. In FIG. 1, the upper casing 140 of the linear deposition apparatus 100 is removed to illustrate the interior of the linear deposition device 100. In actual operation, the linear deposition apparatus 100 is self-contained and insulated to prevent external materials from leaking into the interior of the linear deposition apparatus 100 as well as prevent materials injected by reactors 130 from leaking outside the interior of the linear deposition apparatus 100.

The interior of the linear deposition device 100 may be maintained in vacuum or a predetermined pressure level to facilitate the deposition process and enhance the quality of the layers formed on the substrate 126 by an atomic layer deposition (ALD) process. For this purpose, the linear deposition apparatus 100 may include a pump and pipes (not shown) for discharging gas or air from the interior of the linear deposition device 100.

The linear deposition apparatus 100 is composed of three main parts: a main body 104, a left wing 108 and a right wing 112. A susceptor 120 holding a substrate 126 and a shadow mask 122 moves horizontally between two end positions (at which the susceptor 120 becomes stationary) across the linear deposition apparatus 100 to deposit one or more materials on the substrate 126. During the horizontal movement, parts of the susceptor 120 enter and leave the left wing 108 or the right wing 112.

The main body 104 may include, among other components, reactors 130 for injecting materials and/or radicals onto the substrate 126, a gas valve assembly 132 for injecting materials to or discharging materials from the reactors 130, components for moving the susceptor 120, and components for mounting or unloading the shadow mask 122 and the substrate 126. The left wing 108 and the right wing 112 extend from the main body 104 to provide sufficient space for the susceptor 120 to move during its horizontal movements.

FIG. 1B is a cross-sectional view of the linear deposition apparatus 100 taken along line A-A′ of FIG. 1A, according to one embodiment. As illustrated in FIG. 1, the linear deposition apparatus 100 has an interior enclosed by an upper case 140 and a lower case 144. The reactors 130 are installed above the susceptor 120 to create a small clearance between the upper surface of the susceptor 120 and a lower surface of the reactors 130, typically in the range of 1 mm to 3 mm.

The linear deposition apparatus 100 includes, among other components, components 158 for moving the susceptor 120, components 154 for mounting or unloading the substrate 126, and a control unit 160 for controlling the operation of the components 154, 158. The components 158 for moving the susceptor 120 may include, for example, a linear motor operating under the control of the control unit 160. The components 154 move members and align the shadow mask 122 and the substrate 126, as described below in detail with reference to FIG. 3. The control unit 160 may include a computer for receiving and processing instructions on the operation of the linear deposition apparatus 100.

The left wing 108 and the right wing 112 include injectors 162, 166 for injecting purge gas towards the main body 104 of the linear deposition apparatus 100. The injected purge gas increases pressure within the interior of the left wing 108 and the right wing 112 to effectively prevent materials injected by the reactors 130 or any materials formed as result of mixing between precursors from entering the left wing 108 and the right wing 112. In one or more embodiments, the left wing 108 and/or the right wing 112 may include pyrometers for sensing the temperature. The left wing 108 and/or the right wing 112 may also include sensors for detecting the location of the susceptor 120. The control unit 160 may operate the linear motor based on the location sensors.

In one or more embodiments, the susceptor 120 is placed on a heater 174 for increasing the temperature of the susceptor 120 and the substrate 126. The increased temperature facilitates and enhances the deposition process. The temperature of the susceptor 120 may be maintained within a certain range by detecting the temperature of the substrate by the pyrometers at the left wing 108 and/or the right wing 112 and controlling the amount of energy applied to the heater 174 according to the detected temperature.

FIG. 1C is a cross sectional view of the linear deposition apparatus 100 taken along line B-B′, according to one embodiment. The linear deposition apparatus 100 includes a door 184 through which a substrate for processing can enter into the main body 104 and then be mounted onto the susceptor 120. The same door 184 can be used to remove a processed substrate from the main body 104. The door 184 can be closed after mounting the substrate 126 to seal the interior of the linear deposition apparatus 100.

In one or more embodiments, a robotic arm is used for moving the substrate 126 into or out of the linear deposition apparatus 100. It is generally preferable to reduce the stroke (or the moving distance) of the robotic arm associated with mounting or unloading the substrate.

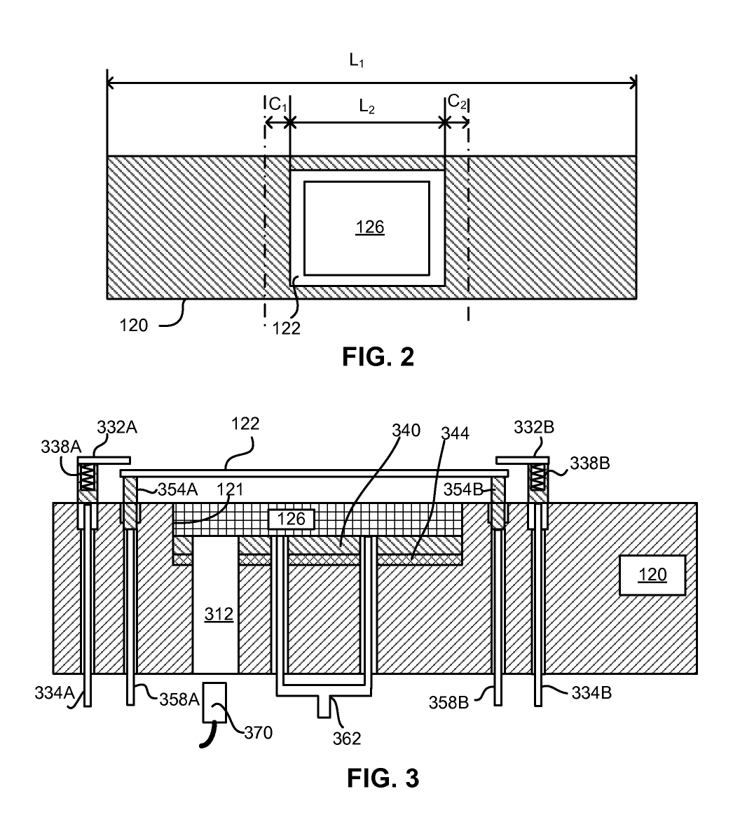

FIG. 2 is a plan view of the susceptor 120 with the substrate 126 and the shadow mask 122 mounted thereon, according to one embodiment. The length L₁ of the susceptor 120 is longer than the length L₂ of the substrate 126 or the shadow mask 122 by at least twice the width W of the reactors 130. Such length of L₁ is the minimum length of the susceptor 120 that allows a part of the susceptor 120 to be present below the reactors 130 even when the susceptor 120 is at the left end position or at the right end position. If the susceptor 120 is not present below the reactors 130, an excessive amount of source precursor and reactant precursor injected may leak out into the interior of the linear deposition apparatus 100. The leaked source precursor and the reactant reactor may then react to produce particles of material in the interior of the linear deposition apparatus 100. To prevent such excess leakage of materials, it is preferable to keep at least part of the susceptor 120 below the reactors 130 in the paths of the source precursor and the reactant precursor even when the susceptor 120 is at the right end position or the left end position.

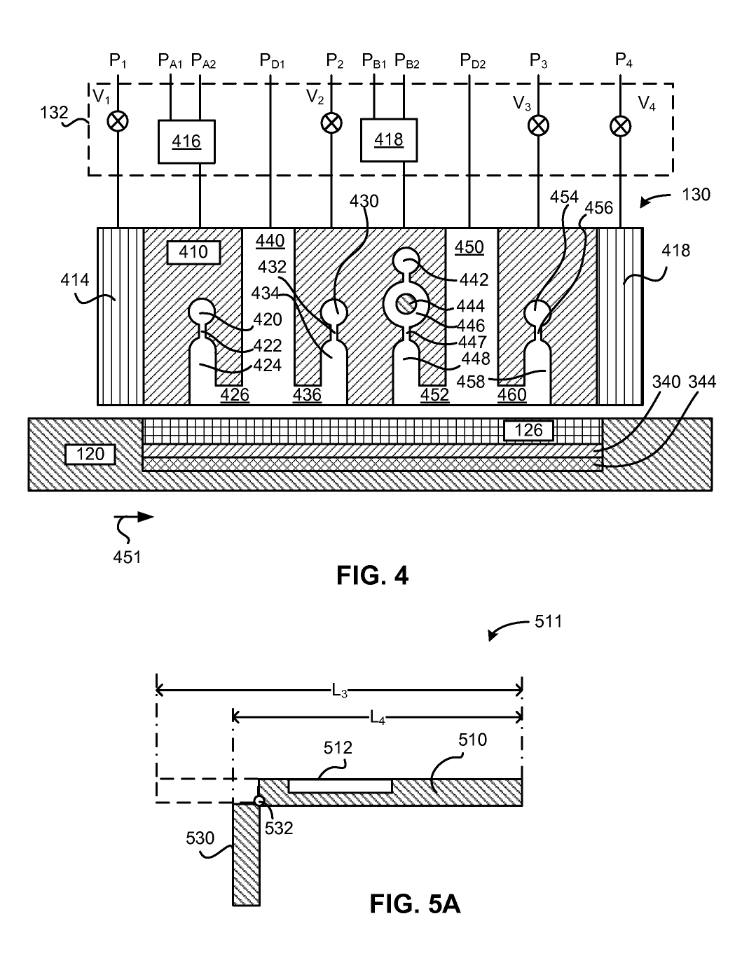

It is generally preferable to move the substrate 126 below the reactors 130 at a constant speed to deposit a layer (or layers) of material in a conformal manner. In order to accelerate the susceptor 120 to a constant speed for depositing the material from the left end position or the right end position or to decelerate the susceptor 120 to stop at the left end position or the right end position, the length L₁ of the susceptor 120 may be increased beyond twice the width W of the reactors 130 plus the length L₂ of the substrate 126 or the shadow mask 122 to include sections C₁, C₂ for accelerating the susceptor 120 from a stationary state to the constant speed and for decelerating the susceptor 120 from the constant speed to the stationary state. In one or more embodiments, the sections C₁, C₂ may also account for the widths of blocks in the reactors 130 for generating gas curtains above the susceptor 120, as described below in detail with reference to FIG. 4.

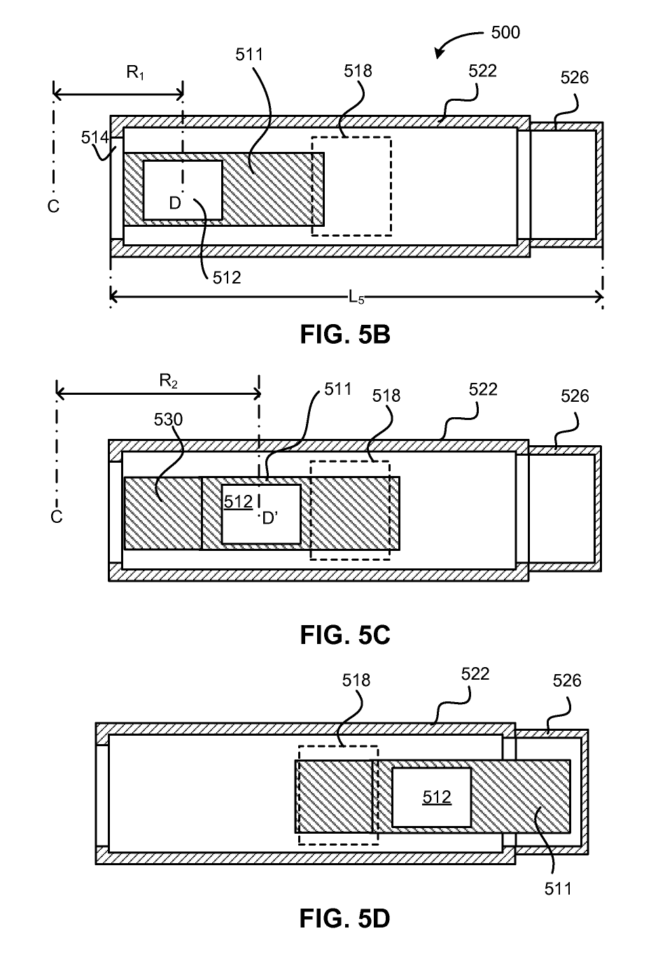

Due to the extended length L₁ of the susceptor 120, the linear deposition apparatus 100 is provided with the left wing 108 and the right wing 112, as described above in detail with reference to FIGS. 1A through 1C. In order to reduce the length of the linear deposition device due to the extended length of a susceptor, a foldable susceptor may be used, as described below in detail with reference to FIGS. 5A through 5C.

FIG. 3 is an enlarged sectional view of the susceptor 120 illustrating a mechanism for mounting or unloading the substrate 126 and the shadow mask 122, according to one embodiment. When mounted and locked, the substrate 126 is placed on a rubber plate 340 which is placed on top of a magnet plate 344. The mounting or unloading mechanism in the susceptor 120 may include, among other components, latches 332A, 332B, shadow mask mounts 354A, 354B, extension rods 334A, 334B connected to the latches 332A, 332B, extension rods 358A, 358B connected to the shadow mask mounts 354A, 354B, lifting rods 362 for raising or lowering the substrate 126, and a camera 370.

The rubber plate 340 increases the friction between the substrate 126 and the susceptor 120 to prevent the relative movement between the substrate 126 and the susceptor 120 during the movement of the susceptor 120. In one embodiment, the rubber plate 340 includes a silicon rubber coated on the magnet plate 344.

The magnet plate 344 is part of the susceptor 120 and functions to secure the metal shadow mask 122 to the top surface of the substrate 126. Although the latches 332A, 332B include springs 338A, 338B to press the metal shadow mask 122 towards the substrate 126 at the edges of the metal shadow mask 122 after the mounting and locking of the metal shadow mask 122, portions of the metal shadow mask 122 may not be pressed securely to the substrate 126. The magnet plate 344 provides additional force to secure the metal shadow mask 122 onto the upper surface of the substrate 126.

The susceptor 120 is formed with a groove 121 to receive the substrate 126. During mounting, the lifting rods 362 are raised in a mounting position. While the lifting rods 362 are placed in the mounting position, a robotic arm moves the substrate 126 through the door 184 onto the lifting rods 362. Then the lifting rods 362 are lowered to place the substrate 126 on the top of the rubber plate 340.

After placing the substrate 126 in the grove 121, the metal shadow mask 122 is moved onto the substrate 126 and secured onto the mounts 354A, 354B. The mounts 354A, 354B are connected to the extension rods 358A, 358B. Each of the extension rods 354A, 354B is moved in a vertical direction and/or a horizontal direction to align the metal shadow mask 122 with the substrate 126. In one embodiment, the camera 370 detects the relative location of a target point on the shadow mask 122 and moves the extension rods 354A, 354B to align the shadow mask 122 with the substrate 126. The substrate 126 is at least partially transparent, and the camera 370 may capture the image of the shadow mask 122 through a hole 312 formed in the susceptor 120.

After the shadow mask 122 is aligned, the extension rods 354A, 354B are lowered and secured onto the substrate 126. The extension rods 334A, 334B may be lowered onto the shadow mask 122 simultaneously with the extension rods 354A, 354B or after the extension rods 354A, 354B are lowered to secure the metal shadow mask 122 in place.

After depositing material(s) on the substrate 126, the substrate 126 may be unloaded by first unlocking the latches 332A, 332B by raising the extension rods 334A, 334B, raising the extension rods 358A, 358B and removing the shadow mask 122, raising the lifting rods 362 and operating the robotic arm to hold and carry the processed substrate 126 out the door 184.

The mounting or unloading mechanism as illustrated in FIG. 3 is merely illustrative. Various other components or mechanisms may be used to mount or unload the substrate.

FIG. 4 is a sectional view of reactors 130 in the linear deposition apparatus 100, according to one embodiment. Although the reactors 130 are illustrated in FIG. 4 as being made of a single body 410, the reactors 130 may include multiple sub-modules each with a separate body. Further, multiple sets of reactors may be placed in tandem to perform deposition of multiple layers of material per a single pass of the substrate 126 below the sets of reactors 130.

In the embodiment of FIG. 4, the reactors 130 may include two purge gas curtain blocks 414, 418 and a body 410 formed with three injectors and a radical reactor. The gas curtain blocks 414, 418 inject purge gas down towards the susceptor 120 to form gas curtains. The gas curtains prevent the injected source precursor and reactant precursor from leaking outside the region below the reactors 130. The purge gas curtain blocks 414, 418 may have curtain plates configured so that the injected purge gas is directed away from the reactors 130. The purge gas for the purge gas curtain blocks 414, 418 are provided via pipe P₁ and valve V₁ or pipe P₄ and valve V₄.

In one embodiment, the temperature of the purge gas (injected by injectors or purge gas curtain blocks) is higher than the temperature at which the source precursor liquefies or solidifies. By retaining the temperature of the purge gas at a high level, the purge efficiency of the gas can be increased.

A first injector is a portion of the body 410 formed with a channel 420, perforations 422, a chamber 424 and a constriction zone 426. For example, a source precursor for performing atomic layer deposition (ALD) may be injected by the first injector onto the substrate 126, as the substrate 126 moves across the first injector from the left to the right as shown by arrow 451. The substrate 126 may also reciprocate in left and right directions. Specifically, the source precursor is provided via pipe P_{A1}, switching valve 416, the channel 420, and the perforation 422 into the chamber 424. Below the chamber 424, the source precursor is adsorbed in the substrate 126. The source precursor remaining without being adsorbed in the substrate 126 passes through the constriction zone 426 and is discharged via an exhaust port 440 connected to pipe P_{D1}.

The constriction zone 426 has a height lower than the height of the chamber 424. Accordingly, as the remaining source precursor passes through the constriction zone 426, the pressure of the source precursor drops and the speed of the source precursor is increased due to Venturi effect. Venturi effect removes physisorbed source precursor from the surface of the substrate 126 while retaining chemisorbed source precursor on the surface of the substrate 126.

A second injector is a portion of the body 410 formed with a channel 430, perforations 434, and a chamber 434. In one embodiment, purge gas is injected via pipe P₂, valve V₂, channel 430, and perforations 432 into the chamber 434. As the purge gas is injected onto the substrate 126 and discharged via a constriction zone 436 (with height lower than the height of the chamber 434), excess source precursor (e.g., physisorbed source precursor) is further removed from the surface of the substrate 126 due to Venturi effect. The purge gas injected via the second injector is also discharged via the exhaust port 440.

A radical reactor is a portion of the body 410 formed with a channel 442, a radical chamber 446, a chamber 448 and a constriction zone 452. Material for generating radicals is injected into the channel 442 via pipe P_{B1} and a switching valve 418. The material is injected into the radical chamber 446 via the perforations connecting the channel 442 and the radical chamber 446. An electrode 444 passes through the radical chamber 446. As a voltage difference is applied between the body 410 and the electrode 444, plasma is generated in the radical chamber 446, creating radicals of the material injected into the radical chamber 446. The generated radicals are injected into the chamber 448 through slit 447 (e.g., slit 447 has 2 mm to 5 mm width or perforations). The radicals come into contact with the portion of the substrate 126 previously adsorbed with the source precursor. The radicals function as reactant precursor for performing ALD. As a result of the source precursor molecules reacting with or being replaced with the radicals, a layer of material is deposited on the substrate 126. Excess radicals or molecules reverted back to an inert state from the radicals may be discharged via an exhaust port 450 and pipe P_{D2}. The constriction zone 452 of the radical reactor performs the same function as the constriction zones 426, 436.

A third injector is a portion of body 410 formed with a channel 454, perforations 456, a chamber 458 and a constriction zone 460. In one embodiment, purge gas is injected into the third injector via pipe P₃ and valve V₃ to remove any redundant material formed as the result of exposing the substrate 126 to the radicals. The purge gas injected via the third injector is discharged via the exhaust port 450. The purge gas is injected to desorb the source precursor molecules and/or the reactant precursor molecules from the substrate 126 and guide the flow of these molecules into exhaust ports 440, 450, thereby preventing precursor molecules from leaking outside a region between the plurality of reactors 130 and the susceptor 120.

Additional purge gas can be injected onto the substrate 126 between reactors, for example, through a path formed between the chamber 434 and the chamber 448. When two sets of reactors are places in tandem, the additional purge gas can be injected onto the substrate 126 between the first set of reactors and the second set of reactors.

In one embodiment, the source precursor injected by the first injector is Trimethylaluminium (TMA) and the radicals injected by the radical reactors as the reactant precursor are O*(oxygen radials). TMA and O* are merely examples of materials or radicals used as the source precursor and the reactant precursor. Various other materials and radicals may be used for depositing materials on the substrate.

Deposition of material on the susceptor 120 and/or formation of material by reaction of the source precursor and the reactant precursor in areas other than on the surface of the substrate is disadvantageous because, among other reasons, particles of the formed material may pollute the interior of the linear deposition apparatus 100. For example, after being exposed to multiple rounds of the source precursor and the reactant precursor, the surface of the susceptor 120 may be deposited with multiple layers of material. As the thickness of the material increases, the layers of material may flake off and become dispersed in the interior of the linear deposition apparatus 100. Therefore, the linear deposition apparatus 100 may include mechanisms for preventing pollution of the interior of the linear deposition apparatus 100 by the material formed through the reaction of the source precursor and the reactant precursor.

One of such mechanisms is to switch off supply of the source precursor or the reactant precursor when the substrate 126 is no longer below the first injector or the radical reactor. In one embodiment, the switching valve 416 connects the channel 420 to pipe P_{A1} when the substrate 126 is passing below the first injector but connects the channel 420 to pipe P_{A2} that provides purge gas when the substrate 126 is no longer below the first injector. By injecting the purge gas instead of the source precursor into the first injector when the substrate 126 is no longer below the substrate 126, the surface of the susceptor 120 is not adsorbed with the source precursor, and hence, no unnecessary layer of material is deposited on the susceptor 120 by mixing with reactant precursor. As a corollary effect, the source precursor is not wasted by being injected on the surface of the susceptor 120.

Similarly, the switching valve 418 connects the channel 442 to pipe P_{B1} when the substrate 126 is passing below the radical reactor. When the substrate 126 is no longer below the radical reactor, the switching valve 418 connects the channel 442 to pipe P_{B2} for injecting purge gas into the channel 442 so that the susceptor 120 is not injected with the radicals of the reactant precursors generated by the radical reactor. By continuing to inject purge gas, plasma within the radical chamber 446 can be retained in a stable state, and the radicals functioning as the reactant precursor can be generated shortly before the substrate 126 passes below the radical reactor by resuming the injection of material via pipe P_{B1}.

Another mechanism to prevent the pollution is by the use of the gas curtain blocks 414, 418. The gas curtain blocks 414, 418 inject purge gas onto the substrate 120 to form gas curtains that prevent the source precursor and the reactant precursor from leaking outside the area between the susceptor 120 and the reactors 130. By reducing the source precursor and the reactant precursor from leaking to other areas of the linear deposition apparatus 100 and reacting in these other areas, the amount of particles formed outside the desired area of the surface of the substrate 126 can be reduced.

Further, the left wing 108 and the right wing 112 include injectors 162, 166 to inject heated purge gas into the interior of the left wing 108 and the right wing 112. The injected heated purge gas functions to prevent the source precursor and the reactant precursor from entering the interior of the left wing 108 and the right wing 112.

In some instances, the length of susceptor for mounting a substrate may be limited for various reasons. For example, a door for mounting the substrate may be placed at one end of a linear deposition apparatus and the stroke of a robotic arm for mounting or unloading the substrate may be limited in distance. Alternatively, the overall length of the linear deposition apparatus may be limited for some reason. To accommodate such design requirements, a susceptor may be made to be foldable at one end.

FIG. 5A is a cross sectional diagram of a foldable susceptor 511 according to one embodiment. The foldable susceptor 511 includes a left body 530 and a right body 510 connected by a hinge 532. The foldable susceptor 511 is folded into a shape shown in FIG. 5A, for example, for loading or unloading a substrate through a robotic arm extending from the left side of the susceptor 511, as described below in detail with reference to FIG. 5B. After loading or unloading of the substrate 512, the left body 530 is raised to be coplanar with the right body 510, as described below in detail with reference to FIGS. 5C and 5D. The unfolded length of the susceptor 511 is L₃ whereas the folded length of the susceptor 511 is L₄ (which is shorter than L₃).

FIG. 5B is a cross sectional view of a linear deposition apparatus 500 illustrating the susceptor 511 positioned at the left end for mounting or unloading of the substrate 512, according to one embodiment. The linear deposition apparatus 500 includes a door 514 at the left end of a body 522 through which a robotic arm may convey the substrate 512 onto or away from the susceptor 511.

Assuming that the robotic arm has to move the substrate 512 to point C from point D or from point C to point D on the susceptor 512, the stroke (or moving distance of) the robotic arm for mounting or unloading the substrate 512 is R₁, as shown in FIG. 5B. Compare this to the case where a non-foldable susceptor is used. When non-foldable susceptor is used, the robotic arm needs to move the substrate 512 to or from point C from or to loading point D′ on the substrate, and the stroke (or moving distance of) the robotic arm for mounting or unloading the substrate 512 is R₂, as shown in FIG. 5C. R₂ is longer than R₁, and hence, the foldable susceptor 512 would result in shorter stroke (or moving distance of) the robotic arm. By reducing the length of the susceptor 511 to L₄ during loading or unloading of the substrate, the stroke of the robotic arm can be reduced from R₂ from R₁. While the substrate 512 is being mounted or unloaded, injection of materials by reactors 518 may be halted.

After the loading of the substrate 512, the left body 530 of the susceptor 511 is raised and moved to the right, as shown in FIG. 5C. As the right side of the susceptor 511 moves below the reactors 518, the injectors 518 resume injection of purge gas and/or source precursor. The substrate 512 passes below the reactors 518 and is exposed to the source precursor and then the reactant precursor for performing ALD. In one embodiment, the reactors 518 have the same structure as the reactors 130 illustrated in FIG. 4.

The susceptor 511 then moves further to the right until the susceptor 511 reaches the right-end position, as illustrated in FIG. 5D. At the right-end position, the right portion of the susceptor 511 is placed in the interior of a right wing 526 of the linear deposition apparatus 500. When further reduction in the length of the linear deposition apparatus 500 is required, not only left body 530 but also right body 510 can be folded. With the folding right body 510, the right wing 526 can be obviated from the linear deposition apparatus 500.

After reaching the right-end position of FIG. 5D, the susceptor 511 moves to the left back to the position as illustrated in FIG. 5C. From the position of FIG. 5D, the susceptor 511 may repeat the movement to the right to deposit additional materials or undergo another process by the reactors 518. Alternatively, the susceptor 511 moves to the mounting or unloading position for unloading, as illustrate in FIG. 5B.

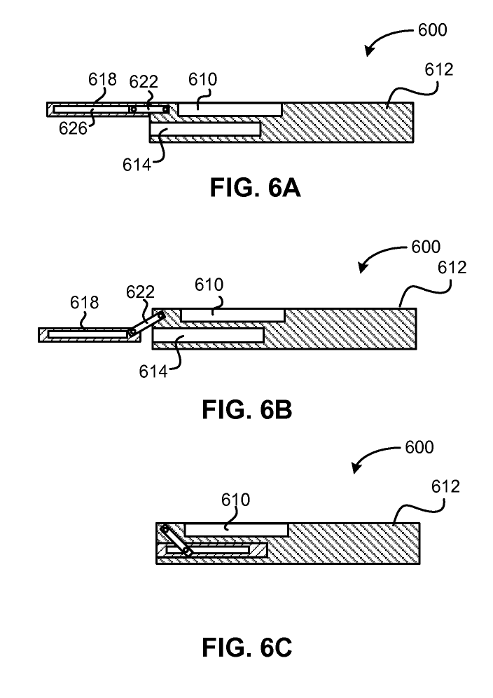

FIGS. 6A through 6C are cross sectional views of a foldable susceptor 600, according to another embodiment. The foldable susceptor 600 includes a right body 612 and a left body 618. The right body 612 and the left body 618 are connected by a link 622. A substrate 610 is mounted on the right body 612. The link 622 has one end hinged to the right body 612, and the other end secured to the left body 618. The link 622 includes a pin that is received in a groove 626 formed in the left body 618 so that the link 622 can rotate and slide relative to the left body 618.

In the unfolded mode illustrated in FIG. 6A, the left body 618 is locked into the raised position and the top surface of the left body 618 is coplanar with the top surface of the right body 612. A mechanism (not shown) for locking the left body 618 may be provided to retain the left body 618 in the unfolded mode.

FIG. 6B is a cross sectional diagram illustrating the lowering of the left body 618, according to one embodiment. In the right body 612, a cavity 614 is formed to receive the left body 618 in a folded mode. After lowering the left body, the left body 618 may be inserted into the cavity 614 to place the susceptor 600 in a folded mode.

The folding configurations of the susceptor in FIG. 5A and FIGS. 6A through 6C are merely illustrative. Susceptor with various other configurations may be used. For example, a susceptor with two body parts that are slidable relative to each other to adjust the total length of the susceptor can be used.

Although the present invention has been described above with respect to several embodiments, various modifications can be made within the scope of the present invention. Accordingly, the disclosure of the present invention is intended to be illustrative, but not limiting, of the scope of the invention, which is set forth in the following claims.

What is claimed is:

1. An apparatus comprising:
a plurality of reactors configured to inject source precursor and reactant precursor for performing the atomic layer deposition on a substrate;
a susceptor mounted with the substrate and moving relative to the plurality of reactors between a first end position and a second end position in a direction that is substantially perpendicular to a direction in which the source precursor and the reactant precursor are injected onto the substrate by the plurality of reactors, wherein a length of the susceptor is longer than the substrate by at least twice the width of the plurality of the reactors to place at least a portion of the susceptor in paths of the injected source precursor and the injected reactant precursor at the first end position and the second end position; and
at least one component configured to move the susceptor between the first position and the second position.

2. The apparatus of claim 1, wherein the plurality of reactors comprise a first injector placed at a first edge facing the first end position and a second injector placed at a second edge facing the second end position to inject purge gas to guide the injected source precursor or the injected reactant precursor towards one or more exhaust ports, and to prevent the injected source precursor or the injected reactant precursor from leaking outside a region between the plurality of reactors and the susceptor.

3. The apparatus of claim 1, further comprising a body, a first wing extending from one end of the body and a second wing extending from an opposite end of the body, wherein the first wing receiving a part of the susceptor when the susceptor is at the first end position, and the second wing receiving another part of the susceptor when the susceptor is at the second end position.

4. The apparatus of claim 3, wherein the body is formed with a door for moving the substrate into or out of interior of the body.

5. The apparatus of claim 3, wherein purge gas is injected into interior of the first wing and the second wing towards the body to prevent the source precursor or the reactant precursor from entering the interior of the first wing and the second wing.

6. The apparatus of claim 1, wherein the plurality of reactors comprise at least one radical reactor for generating radicals.

7. The apparatus of claim 1, wherein the susceptor further comprises one or more latches for securing a shadow mask onto the substrate.

8. The apparatus of claim 7, further comprising a camera for aligning the shadow mask and the substrate, the latches configured to lock the shadow mask and the substrate after the shadow mask and the substrate are aligned.

9. The apparatus of claim 6, further comprising lifting rods placed below the substrate to lift the substrate from the susceptor for unloading the substrate from the susceptor.

10. The apparatus of claim 1, wherein the susceptor is configured to fold to reduce a length of the susceptor when mounting or unloading the substrate.

11. The apparatus of claim 10, wherein the susceptor comprises a first part and a second part hinged to the first part, the first part rotated relative to the second part when mounting or unloading the substrate.

12. The apparatus of claim 10, wherein the susceptor comprises a first part and a second part connected to the first part via a link, the second part formed with a cavity to hold the first part when the susceptor is folded.

13. The apparatus of claim 10, wherein a door for moving the substrate into or out of interior of the body is formed at a side of the body adjacent to a part of the susceptor being folded.

14. The apparatus of claim 1, wherein the plurality of reactors comprise a first reactor for injecting the source precursor and a second reactor for injecting the reactant precursor.

15. The apparatus of claim 14, wherein the substrate moves across the first reactor and the second reactor at a constant speed to deposit a material on the substrate.

16. The apparatus of claim 14, further comprising a valve assembly connected to the first reactor to provide the source precursor to the first reactor while the substrate passes across the first reactor but provide purge gas to the first reactor before or after the substrate passes across the first reactor, the valve assembly connected to the second reactor to provide the reactant precursor to the second reactor while the substrate passes across second reactor but provide purge gas to the second reactor before or after the substrate passes across the second reactor.

17. The apparatus of claim 14, further comprising a third reactor and a fourth reactor for injecting purge gas onto the substrate to remove physisorbed precursor or material from the substrate.

18. An apparatus comprising:
a first reactor configured to inject source precursor;
a second reactor configured to inject reactant precursor;
a susceptor mounted with the substrate and moving relative to the first and second reactors between a first end position and a second end position in a direction that is substantially perpendicular to a direction in which the source precursor and the reactant precursor are injected onto the substrate by the first and second reactors;
a valve assembly connected to the first and second reactors to provide the source precursor to the first reactor while the substrate passes across the first reactor but provide purge gas to the first reactor before or after the substrate passes across the first reactor, the valve assembly connected to the second reactor to provide the reactant precursor to the second reactor while the substrate passes across second reactor but provide purge gas to the second reactor before or after the substrate passes across the second reactor; and
at least one component configured to move the susceptor between the first position and the second position.

19. The apparatus of claim 18, wherein the valve assembly comprises a first switching valve for selectively providing the source precursor or the purge gas to the first reactor, and a second switching valve for selectively providing the source precursor or the purge gas to the second reactor.

20. The apparatus of claim 18, further comprising third and fourth reactor for injecting purge gas onto the susceptor to prevent leakage of the source precursor and the reactant precursor.
